(19) United States
(12) Patent Application Publication
(10) Pub. No.: US 2021/0235026 A1
(43) Pub. Date: Jul. 29, 2021

(54) PIXEL AND IMAGE SENSOR

(71) Applicant: SZ DJI TECHNOLOGY CO., LTD., Shenzhen (CN)

(72) Inventor: Ze XU, Shenzhen (CN)

(21) Appl. No.: 17/214,565

(22) Filed: Mar. 26, 2021

Related U.S. Application Data
(63) Continuation of application No. PCT/CN2018/107863, filed on Sep. 27, 2018.

(51) Int. Cl. H04N 5/357; H04N 5/3745

(52) U.S. Cl. CPC H04N 5/357; H01L 27/14603; H04N 5/3745

(57) ABSTRACT

A pixel includes a photoelectric converter, a transfer transistor, a reset transistor, a first source follower, a second source follower, and a switch device. A gate of the first source follower and a gate of the second source follower are electrically connected to a floating diffusion region between the transfer transistor and the reset transistor, and a source of the first source follower and a source of the second source follower are connected to a row selection line via a select transistor. The switch device is connected to the second source follower and used to be turned on to allow the second source follower to work simultaneously with the first source follower, or to be turned off to allow the first source follower to work while the second source follower does not work.

### CROSS-REFERENCE TO RELATED APPLICATION

This application is a continuation of International Application No. PCT/CN2018/107863, filed Sep. 27, 2018, the entire content of which is incorporated herein by reference.

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The present disclosure relates to the field of image signal processing and, in particularly, to a pixel and image sensor.

### BACKGROUND

Nowadays, image information needs to be collected in many fields, such as consumer electronics, security automation, artificial intelligence, and the Internet of Things. Therefore, image sensors are widely used in various fields.

An image sensor usually includes multiple pixels. A signal-to-noise ratio of an image signal output by a pixel is an important indicator of the pixel. The signal-to-noise ratio of the image signal output by the pixel is not stable and may change with changes of environment and other factors, which is difficult to control.

### SUMMARY

In accordance with the disclosure, there is provided a pixel including a photoelectric converter, a transfer transistor, a reset transistor, a first source follower, a second source follower, and a switch device. A gate of the first source follower and a gate of the second source follower are electrically connected to a floating diffusion region between the transfer transistor and the reset transistor, and a source of the first source follower and a source of the second source follower are connected to a row selection line via a select transistor. The switch device is connected to the second source follower and used to be turned on to allow the second source follower to work simultaneously with the first source follower, or to be turned off to allow the first source follower to work while the second source follower does not work.

Also in accordance with the disclosure, there is provided an image sensor including a pixel array which includes a pixel, and a control circuit. The pixel includes a photoelectric converter, a transfer transistor, a reset transistor, a first source follower, a second source follower, and a switch device. A gate of the first source follower and a gate of the second source follower are electrically connected to a floating diffusion region between the transfer transistor and the reset transistor, and a source of the first source follower and a source of the second source follower are connected to a row selection line via a select transistor. The switch device is connected to the second source follower and used to be turned on to allow the second source follower to work simultaneously with the first source follower, or to be turned off to allow the first source follower to work while the second source follower does not work. The control circuit is connected to the switch device in the pixel and used to control whether the second source follower and the first source follower work simultaneously.

In accordance with the disclosure, there is provided a pixel including a photoelectric converter, a first transfer transistor, a reset transistor, a source follower, a second transfer transistor, and a switch device. A gate of the source follower is electrically connected to the floating diffusion region between the first transfer transistor and the reset transistor, and a source of the source follower is connected to the select transistor via the row selection line. One of a source and a second drain of the second transfer transistor is connected to an output terminal of the photoelectric converter, and another one of the source and the drain of the second transfer transistor is connected to the floating diffusion region. The switch device is connected to the second source follower and used to be turned on to allow the second source follower to work simultaneously with the first source follower, or to be turned off to allow the first source follower to work while the second source follower does not work.

Also in accordance with the disclosure, there is provided an image sensor including the pixel array which includes the pixel, and the control circuit. The pixel includes a photoelectric converter, a first transfer transistor, a reset transistor, a source follower, a second transfer transistor, and a switch device. A gate of the source follower is electrically connected to the floating diffusion region between the first transfer transistor and the reset transistor, and a source of the source follower is connected to the select transistor via the row selection line. One of a source and a second drain of the second transfer transistor is connected to an output terminal of the photoelectric converter, and another one of the source and the drain of the second transfer transistor is connected to the floating diffusion region. The switch device is connected to the second source follower and used to be turned on to allow the second source follower to work simultaneously with the first source follower, or to be turned off to allow the first source follower to work while the second source follower does not work. The control circuit connected to the switch device in the pixel and used to control whether the second transfer transistor and the first transfer transistor work simultaneously.

### BRIEF DESCRIPTION OF THE DRAWINGS

FIG. 1 is a circuit diagram of an example pixel.

FIG. 2 is a circuit diagram of a pixel according to an example embodiment.

FIG. 3 is an example diagram of a circuit layout of the pixel shown in FIG. 2.

FIG. 4 is a schematic structural diagram of an image sensor according to an example embodiment.

FIG. 5 is an example diagram of a circuit layout of the image sensor shown in FIG. 4.

FIG. 6 is a circuit diagram of a pixel according to another example embodiment.

FIG. 7 is an example diagram of a circuit layout of the pixel shown in FIG. 6.

FIG. 8 is a schematic structural diagram of an image sensor according to another example embodiment.

FIG. 9 is an example diagram of a circuit layout of the image sensor shown in FIG. 8.

### DETAILED DESCRIPTION OF THE EMBODIMENTS

An image sensor may include a pixel array and a signal processing circuit. An area where the pixel array is located may be called a photosensitive circuit area of the image sensor. The pixel array may include a plurality of pixels, such as tens of thousands or even hundreds of millions of pixels. The pixel may sometimes be called a photosensitive unit. The pixel may be used to convert a received light signal into an analog signal.

The area where the signal processing circuit is located may be called a peripheral circuit area of the image sensor. The signal processing circuit is electrically connected to the pixel array and may be used to convert the analog signal output by the pixel array to a digital signal for representing image information collected by the pixel.

FIG. 1 is a circuit diagram of an example pixel 10. As shown in FIG. 1, the pixel 10 includes a photodiode PD, a transfer transistor TX, a source follower SF, a reset transistor RST, and a select transistor SEL.

The photodiode PD may be used to convert received photons into electrons (i.e., output photoelectrons). The photodiode PD in FIG. 1 may be replaced by another device with a photoelectric conversion function, such as a phototriode or a photomultiplier.

The transfer transistor TX may be used to transfer the photoelectrons output by the photoelectric converter to the floating diffusion region FD located between the transfer transistor TX and the reset transistor RST.

The floating diffusion region FD may have a charge-voltage conversion function. The floating diffusion region FD may be understood as a transistor parasitic capacitor, which may be used to induce a corresponding voltage signal according to an amount of charge output by the transfer transistor TX.

The reset transistor RST is used to reset the pixel for a next signal collection.

A gate of the source follower SF is connected to the floating diffusion region FD, and a source of the source follower SF may be connected to a row selection line (not shown in FIG. 1). The source follower SF may be used to receive a voltage signal of the floating diffusion region FD and generate a follow signal of the voltage signal of the floating diffusion region FD (or the output signal of the source follower SF). The follow signal may be the voltage signal obtained by shifting the potential of the voltage signal of the floating diffusion region FD.

The select transistor SEL may be used to receive the control signal input by an external control circuit. The control circuit may be, for example, the signal processing circuit of the image sensor including the pixel 10. When the control circuit controls the select transistor SEL to be turned on, the source follower SF may output a corresponding follow signal to the row selection line.

A transistor noise of a source follower is an important part of an overall noise of the pixel. The noise of a source follower is related to a size of the source follower. Generally speaking, the larger the size of the source follower, the lower the noise. Therefore, to improve a signal-to-noise ratio of the image signal, one possible implementation is to connect multiple source followers in the pixel in parallel to increase the size of the source followers and reduce the noise of the source followers. However, as shown in FIG. 1, the gate of the source follower SF is electrically connected to the floating diffusion region FD, which means that a gate capacitance of the source follower SF is a part of a total capacitance of the floating diffusion region FD. Therefore, a parallel implementation of multiple source followers may reduce the noise of the source followers but increase the total capacitance of the floating diffusion region, thereby reducing a charge/voltage gain of a floating diffusion region. If the signal received by the photoelectric converter is relatively strong (e.g., working in a bright scene), a parallel connection of multiple source followers may usually improve the signal-to-noise ratio of the image signal. However, if the signal received by the photoelectric converter is relatively weak (e.g., working in a dark scene), an increasing in the total capacitance of the floating diffusion region caused by the parallel connection of multiple source followers may reduce the signal-to-noise ratio of the image signal output by the pixel.

It may be seen from above discussion that the size of the source follower and the total capacitance of the floating diffusion region are contradictory. This may cause the signal-to-noise ratio of the image signal output by the pixel to be unstable and difficult to control.

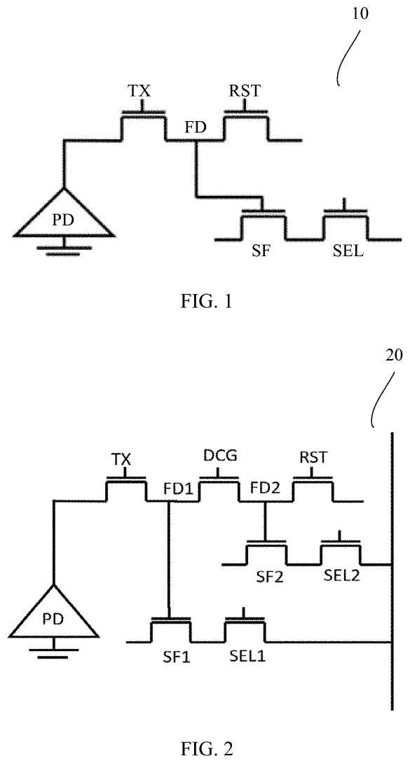

A pixel consistent with the embodiments of the present disclosure that solves the above problem will be described in detail below with reference to FIG. 2.

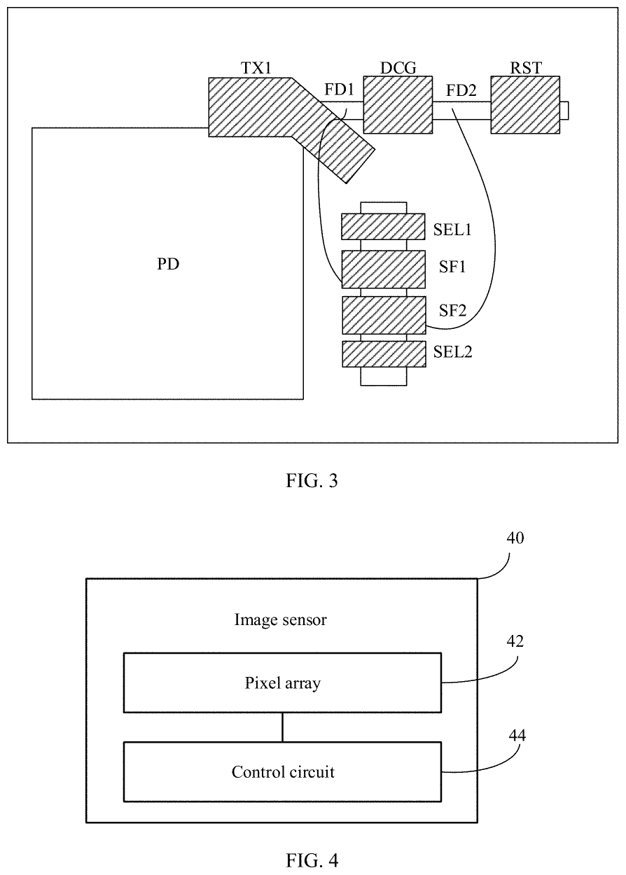

FIG. 2 is a circuit diagram of a pixel 20 according to an example embodiment. As shown in FIG. 2, the pixel 20 includes the photodiode PD, the transfer transistor TX, the reset transistor RST, a first source follower SF1, a second source follower SF2, a switch transistor DCG (such as a dual conversion gain transistor), a first select transistor SEL1, and a second select transistor SEL2. FIG. 3 shows an example circuit layout of the pixel 20 in FIG. 2.

The photodiode PD in FIG. 2 may be replaced by a photoelectric converter of another type, such as a phototriode or a photomultiplier.

For positions and functions of the photodiode PD, the transfer transistor TX, and the reset transistor RST, reference may be made to descriptions of those above in connection with FIG. 1, which are omitted here.

One end of the switch transistor DCG is connected to the transfer transistor TX, and the other end of the switch transistor DCG is connected to the reset transistor RST. As such, the floating diffusion region between the transfer transistor TX and the reset transistor RST may be divided into a first floating diffusion region FD1 located between the transfer transistor TX and the switch transistor DCG, and a second floating diffusion region FD2 located between the switch transistor DCG and the reset transistor RST.

The first source follower SF1 and the second source follower SF2 are source followers connected in parallel. It should be noted that the embodiments of the present disclosure only take the pixel 20 including two source followers as an example for description. In some embodiments, the pixel 20 may include more source followers.

The gate of the first source follower SF1 is connected to the first floating diffusion region FD1 (a connection between circuit devices in this disclosure is electrical connection), and the gate of the second source follower SF2 is connected to the second floating diffusion region FD2. The source of the first source follower SF1 may be connected to the row selection line via the first select transistor SEL1, and the source of the second source follower SF2 may be connected to the row selection line via the second select transistor SEL2.

As shown in FIG. 2, when the switch transistor DCG is turned on, the second source follower SF2 and the first source follower SF1 may work simultaneously. When the switch transistor DCG is tuned off, the first source follower SF1 works while the second source follower SF2 does not work.

The switch transistor DCG may be replaced by another type of switch device as long as a line where the switch device is located may be controlled to be turned on and off.

As shown in FIG. 2, a switch device (i.e., the switch transistor DCG) is located in the floating diffusion region between the transfer transistor TX and the reset transistor RST. In fact, the example embodiment of the present disclosure does not limit the specific position of the switch device as long as it may control whether the second source follower SF2 and the first source follower SF1 work simultaneously. For example, the switch device may also be located between the floating diffusion region and the gate of the second source follower SF2.

Consistent with the disclosure, the first source follower SF1 and the second source follower SF2 are introduced and the switch device is used to control whether the first source follower SF1 and the second source follower SF2 work simultaneously. It is equivalent to increasing the size of a source follower in the pixel 20 when the first source follower SF1 and the second source follower SF2 work simultaneously, thereby reducing the noise of the pixel 20. When the first source follower SF1 works while the second source follower SF2 does not work, the gate capacitance of the first source follower SF1 may be relatively small, and the capacitance of the floating diffusion region may also be relatively small, which may increase the charge/voltage gain of the floating diffusion region.

Therefore, in the embodiments of the present disclosure, the size of the source follower of the pixel and the charge/voltage gain of the floating diffusion region may be weighed according to actual needs to effectively control the signal-to-noise ratio of the image signal output by the pixel.

A dark scene and a bright scene are taken as examples to describe a control method of the pixel 20 in detail below.

For example, in the dark scene, when the pixel 20 is exposed to light, the transfer transistor TX is turned off, and the gates of both the reset transistor RST and the switch transistor DCG are connected to a high voltage to cause both the reset transistor RST and the switch transistor DCG to be turned on. The drain of the reset transistor RST is connected to the high voltage to cause both the first select transistor SEL1 and the second select transistor SEL2 to be turned off. After the exposure is over, the signal starts to be read, the gate of the switch transistor DCG is set to a low voltage, the switch transistor DCG is turned off, and the floating diffusion region FD1 is floated at a high voltage. Then, the gate of the first select transistor SEL1 is placed at a high voltage, and the source of the first select transistor SEL1 is at a voltage value V_{ref} along with the voltage of the first floating diffusion region FD1, which serves as a reference voltage. Then the transfer transistor TX is placed at a high voltage to cause the transfer transistor TX to be turned on. After photoelectrons output by the photodiode PD enter the first floating diffusion region FD1, the transfer transistor TX is turned off. The voltage of the first floating diffusion region FD1 decreases due to the input of the photoelectrons from the photodiode PD, and the source of the first source follower SF1 decreases as the voltage of the first floating diffusion region FD1 decreases. The voltage of the first floating diffusion region FD1 after the decreasing is V_{sig}. A voltage difference between the voltage V_{ref} and the voltage V_{sig} may be regarded as a signal value corresponding to an incident light signal, and the voltage difference may be processed by a subsequent circuit to convert brightness and color information collected by the pixel. Because only the first source follower SF1 works in this scenario, the total capacitance of the floating diffusion region of the pixel 20 is relatively small, and the charge/voltage gain of the floating diffusion region is relatively large. Therefore, even in the dark scene, the voltage signal (V_{ref}−V_{sig}) of the floating diffusion region is still relatively large, and the signal-to-noise ratio of the image signal output by the pixel 20 is still relatively high.

For example, in the bright scene, when the pixel 20 is exposed to light, the transfer transistor TX is turned off, and the gates of both the reset transistor RST and the switch transistor DCG are connected to a high voltage to cause both to be turned on. The drain of the reset transistor RST is connected to a high voltage to cause both the first select transistor SEL1 and the second select transistor SEL2 to be turned off. After the exposure is over, the signal is started to be read, the gate of the reset transistor RST is set to a low voltage to cause the reset transistor RST to be turned off, and the first floating diffusion region FD1 and the second floating region FD2 are electrically connected that both have the same voltage and are floated at a high voltage. Then, the first select transistor SEL1 and the second select transistor SEL2 are placed at a high voltage simultaneously, and the sources of both the select transistors SEL1 and the second select transistor SEL2 are at the voltage value V_{ref} along with the voltage of both the first floating diffusion region FD1 and the second floating diffusion region FD2, which serves as a reference voltage. Then, the transfer transistor TX is placed at a high voltage to cause the transfer transistor TX to be turned on. After photoelectrons output by the photodiode PD enter the first floating diffusion region FD1 and the second floating diffusion region FD2, the transfer transistor TX is turned off. The voltage of both the first floating diffusion region FD1 and the second floating diffusion region FD2 decreases due to the output of the photoelectrons by the photodiode PD, and the sources of both the first follower SF1 and the second follower SF2 decrease as the voltage decreasing of both the first floating diffusion region FD1 and the second floating diffusion region FD2, and the voltage after the decreasing is V_{sig}. A voltage difference between V_{ref} and V_{sig} may regarded as a signal value corresponding to an incident light signal, and the voltage difference may be processed by a subsequent circuit to convert brightness and color information collected by the pixel. Because the first source follower SF1 and the second source follower SF2 work simultaneously in this scenario, which is equivalent to the increasing of the size of the source followers, the noise of the source follower is relatively small to cause the signal-to-noise ratio of the image signal output by the pixel to be maintained at a relatively high value in the bright scene.

FIG. 4 is a schematic structural diagram of an image sensor 40 according to an example embodiment. The image sensor may be a complementary metal oxide semiconductor (CMOS) image sensor. The image sensor (or chip) may be widely used in many fields, such as consumer electronics, security automation, artificial intelligence, and the Internet of Things, and etc. The image sensor may be used to collect and organize image information, providing an information source for subsequent processing and applications.

As shown in FIG. 4, the image sensor 40 includes a pixel array 42 and a control circuit 44. Each of one or more pixels in the pixel array 42 can be the above-described pixel 20.

The control circuit 44 may be a signal processing circuit of the image sensor 40. The control circuit 44 may be connected to the switch device of the pixel 20 and used to control whether the second source follower SF2 and the first source follower SF1 work simultaneously via the switch device.

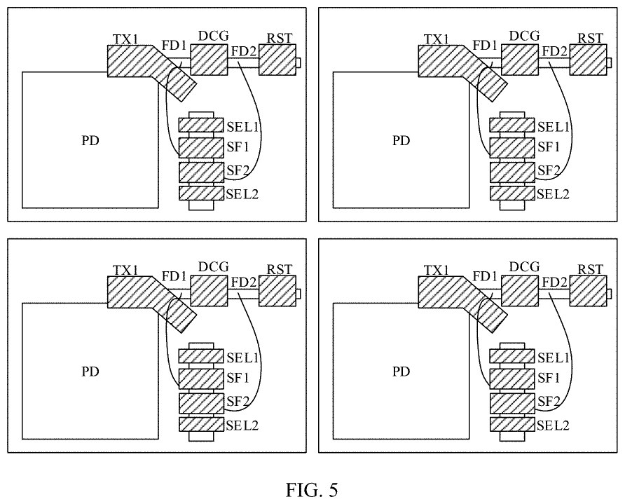

Assuming the pixel array 62 is a 2×2 pixel array, and each pixel in the pixel array 62 is the pixel 20 as shown in FIG. 2, an example of the circuit layout of the pixel array 62 is shown in FIG. 5.

Referring again to FIG. 1, in general, a pixel with a relatively large size usually has a relatively large photosensitive area and sufficient amount of light input, and hence requires that the photodiode PD (or another type of photoelectric converter) thereof have a relatively large number of full well electrons.

Therefore, to transfer a large number of photoelectrons to the floating diffusion region FD of a large-size pixel, the transfer transistor TX with a relatively large size is arranged between the photodiode PD and the floating diffusion region FD.

However, the transfer transistor TX with the relatively large size may introduce a relatively large parasitic capacitance between the floating diffusion region FD and the transfer transistor TX, resulting in a relatively large total capacitance of the floating diffusion region FD and a relatively small charge/voltage gain. When light is relatively weak or exposure time is relatively short, the number of electrons induced by the photodiode PD is relatively small. In this scenario, if the total capacitance of the floating diffusion region FD is relatively large, a voltage signal generated by the floating diffusion region FD may be relatively small, thereby reducing the signal-to-noise ratio of the image signal output by the pixel in the dark scene.

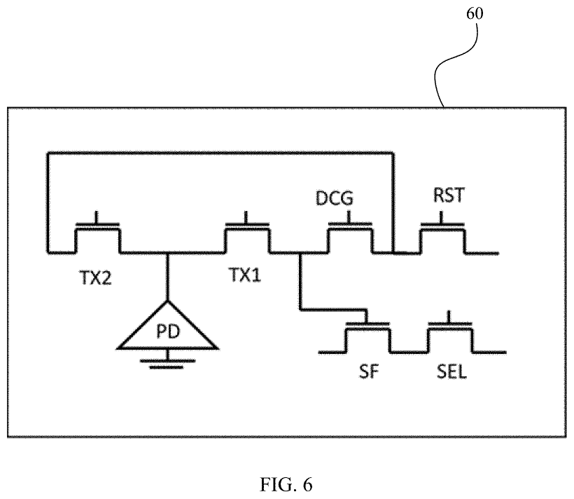

FIG. 6 is a circuit diagram of a pixel 60 according to another example embodiment. In response to the foregoing problem, as shown in FIG. 6, the pixel 60 includes the photodiode PD, a first transfer transistor TX1, a second transfer transistor TX2, the reset transistor RST, the source follower SF, the switch transistor DCG, and the select transistor SEL.

The photodiode PD may be used to convert received photons into electrons (i.e., output photoelectrons). The photodiode PD may also be replaced by a photoelectric converter of another type, such as a phototriode or a photomultiplier.

For positions and functions of the photodiode PD, the first transfer transistor TX1, the reset transistor RST, the source follower SF, and the select transistor SEL, reference may be made to descriptions of those above in connection with FIG. 1, which are omitted here.

A first terminal and a second terminal of the second transfer transistor TX2 are electrically connected to an output terminal of the photodiode PD and the floating diffusion region, respectively. The first terminal may be the source of the second transfer transistor TX2, and the second electrode may be the drain of the second transfer transistor TX2. Or the first terminal may be the drain of the second transfer transistor TX2, and the second terminal may be the source of the second transfer transistor TX2.

One end of the switch transistor DCG is connected to the first transfer transistor TX1, and the other end of the switch transistor DCG is connected to the reset transistor RST. As such, the floating diffusion region between the first transfer transistor TX1 and the reset transistor RST may be divided into the first floating diffusion region FD1 located between the first transfer transistor TX1 and the switch transistor DCG, and the second floating diffusion region FD2 located between the switch transistor DCG and the reset transistor RST. The second terminal of the second transfer transistor TX2 is connected to the second floating diffusion region FD2.

The switch transistor DCG may also be replaced by switch device of another type, as long as a line where the switch device is located may be controlled to be turned on and off.

The switch transistor DCG may also be located between the second terminal of the second transfer transistor TX2 and the floating diffusion region (located between the first transfer transistor TX1 and the reset transistor RST), which may also control whether the second transfer transistor TX2 and the first transfer transistor TX1 work simultaneously.

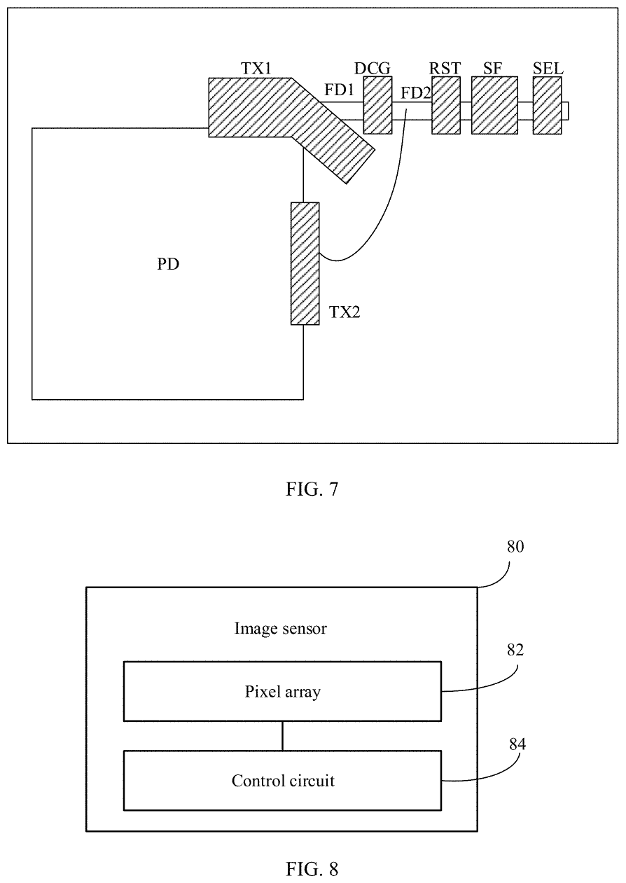

An example circuit layout of the pixel 60 is shown in FIG. 7. As shown in FIG. 7, an overlapping part of silicon of the first transfer transistor TX1 and the silicon of the first floating diffusion region FD1 is relatively small, and the area of the corresponding first floating diffusion region FD1 is also relatively small, therefore the total capacitance of the floating diffusion region FD1 is also relatively small.

The embodiments of the disclosure do not specifically limit the sizes of the first transfer transistor TX1 and the second transfer transistor TX2. In some embodiments, the size of the second transfer transistor TX2 is set to be larger than the size of the first transfer transistor TX1, to cause the second transfer transistor TX2 to transfer as many electrons as possible to the floating diffusion region when the second transfer transistor TX2 works, and to cause the first transfer transistor TX1 to have as little influence as possible on the total capacitance of the floating diffusion region when the second transfer transistor TX2 does not work.

The embodiments of the disclosure do not specifically limit simultaneous working conditions of the first transfer transistor TX1 and the second transfer transistor TX2, which may be selected according to actual needs. For example, in a bright scene, the number of electrons generated by the photodiode PD is relatively large, and the first transfer transistor TX1 and the second transfer transistor TX2 may be controlled to work simultaneously. For example, in a dark scene, the number of electrons generated by the photodiode PD is relatively small, and the second transfer transistor TX2 may be controlled not to work. The above-described control operation may be performed by a control circuit other than the pixel 60. The control circuit may be, for example, a signal processing circuit in the image sensor where the pixel 60 is located.

A dark scene and a bright scene are taken as examples to describe the control method of the pixel 60 in detail below.

For example, in the dark scene, when the pixel 60 is exposed to light, the first transfer transistor TX1, the second transfer transistor TX2, and the select transistor SEL are all turned off. Both the switch transistor DCG and the reset transistor RST are turned on, and a drain of the reset transistor RST is at a high voltage.

After the exposure is over, the switch transistor DCG is controlled to be turned off and the select transistor SEL is controlled to be turned on. In this scenario, the first floating diffusion region FD1 is floated at a high voltage, and a first reference voltage V_{ref1} is read from the source of the select transistor SEL. Then, the first transfer transistor TX1 may be turned on, and the electrons of the photodiode PD are transferred to the first floating diffusion region FD1. The voltage of the first floating diffusion region FD1 may decrease, a first signal voltage V_{sig1} is read at the source of the select transistor SEL, and V_{ref1}−V_{sig1} is the voltage signal corresponding to an intensity of an incident light.

A peripheral circuit (e.g., a signal processing circuit) of the image sensor may image an image via conversion read processing. In this scenario, because the capacitance of the first floating diffusion region FD1 is relatively small, the charge/voltage gain of the first floating diffusion region FD1 is relatively high. Therefore, even in the dark scene, the signal-to-noise ratio of the image signal output by the pixel 60 still maintains at a relatively high value.

For example, in the bright scene, when the pixel 60 is exposed to light, the first transfer transistor TX1, the second transfer transistor TX2, and the select transistor SEL are all turned off, both the switch transistor DCG and the reset transistor RST are turned on, and the drain of the reset transistor RST is at a high voltage.

After the exposure is over, the reset transistor RST is controlled to be turned off and the select transistor SEL is controlled to be turned on. In this scenario, the first floating diffusion region FD1 and the second floating diffusion region FD2 are connected to each other and both are floated at a high voltage, and the second reference voltage V_{ref2} is read at the source of the select transistor SEL. Then both the first transfer transistor TX1 and the second transfer transistor TX2 are turned on simultaneously. Electrons of the photodiode PD are transferred to the first floating diffusion region FD1 and the second floating diffusion region FD2, the voltages of both the first floating diffusion region FD1 and the second floating diffusion region FD2 may decrease, and the second signal voltage V_{sig2} may be read at the source of the select transistor SEL. V_{ref2}−V_{sig2} is the voltage signal corresponding to an intensity of an incident light.

A peripheral circuit (e.g., a signal processing circuit) of the image sensor may image the image via conversion read processing. Because the number of electrons in the photodiode PD in the bright scene is relatively large, simultaneous turning-on of the first transfer transistor TX1 and the second transfer transistor TX2 is beneficial to transfer the photoelectrons output by the photodiode PD to the floating diffusion region quickly and completely.

It may be seen that the pixel shown in FIG. 6 may achieve high charge/voltage gain and high signal-to-noise ratio when the signal is relatively small in the dark scene, and may achieve complete charge transfer as much as possible to cause a final output image signal to have a relatively large dynamic range when the signal is relatively strong.

FIG. 8 is a schematic structural diagram of the image sensor 80 according to another example embodiment. The image sensor may be a complementary metal oxide semiconductor (CMOS) image sensor. The image sensor (or chip) may be widely used in many fields, such as consumer electronics, security automation, artificial intelligence, and the Internet of Things, and etc. The image sensor may be used to collect and organize image information, providing an information source for subsequent processing and applications.

As shown in FIG. 8, the image sensor 80 includes a pixel array 82 and a control circuit 84. Each of one or more pixels in the pixel array 82 can be the above-described pixel 60.

The control circuit 84 may be a signal processing circuit of the image sensor 80. The control circuit 84 may be connected to the switch device of the pixel 60 and used to control whether the second transfer transistor TX2 and the first transfer transistor TX1 work simultaneously via the switch device.

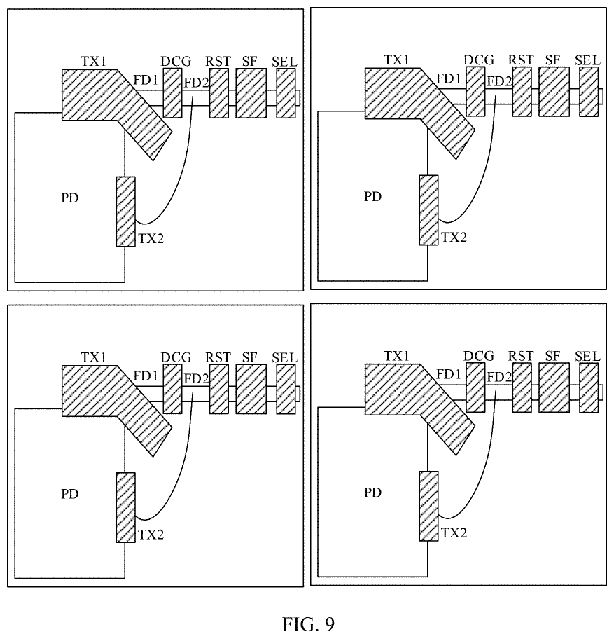

Assuming the pixel array 82 is a 2×2 pixel array, and each pixel in the pixel array 82 is the pixel shown in FIG. 7, an example of the circuit layout of the pixel array 82 is shown in FIG. 9.

The embodiments shown in FIG. 6 and the embodiments shown in FIG. 2 may be combined with each other. For example, the switch transistor DCG may be used to simultaneously control whether the second transfer transistor TX2 and the second source follower SF2 work simultaneously with the first transfer transistor TX1 and the first source follower SF1.

Embodiments of the present disclosure may be implemented in whole or in part by software, hardware, firmware, or any other combination. To be implemented by software, it may be implemented in the form of a computer program product in whole or in part. The computer program product includes one or more computer instructions. When the computer program instructions are loaded and executed on a computer, all or part of the processes or functions described in the embodiments of the present disclosure are performed. The computer may be a general-purpose computer, a special-purpose computer, a computer network, or another programmable device. The computer instructions may be stored in a computer-readable storage medium or transmitted from one computer-readable storage medium to another computer-readable storage medium. For example, the computer instructions may be transmitted from a website, computer, server, or data center to another website, computer, server, or data center via wired manner (e.g., coaxial cable, optical fiber, digital subscriber line, i.e., DSL) or wireless manner (e.g., infrared, wireless, microwave, etc.). The computer-readable storage medium may be any available medium that may be accessed by a computer or a data storage device, such as a server or a data center, integrated with one or more available medium. The storage medium may be a magnetic medium (e.g., a floppy disk, a hard disk, a magnetic tape), an optical medium (e.g., a digital video disc, i.e., DVD), or a semiconductor medium (e.g., a solid-state disk, i.e., SSD), etc.

It should be noted that, when there is no conflict, the above-described embodiments and/or the technical features of the embodiments may be combined with each other, and the technical solutions obtained after the combination should also fall within the scope of the present disclosure.

The units and algorithm steps of the examples described in the embodiments disclosed herein may be implemented by electronic hardware or a combination of computer software and electronic hardware. Whether these functions are executed by hardware or software depends on the specific application and design constraint conditions of the technical solution. Different methods may be used for each specific application to implement the described functions, but such implementation should not be considered beyond the scope of the present disclosure.

The disclosed system, apparatuses, and methods may be implemented in other manners not described here. For example, the devices described above are merely illustrative. For example, the division of units may only be a logical function division, and there may be other ways of dividing the units. For example, multiple units or components may be combined or may be integrated into another system, or some features may be ignored, or not executed. Further, the coupling or direct coupling or communication connection shown or discussed may include a direct connection or an indirect connection or communication connection through one or more interfaces, devices, or units, which may be electrical, mechanical, or in other forms.

The units described as separate components may or may not be physically separated, and the components shown as units may or may not be physical units. That is, the units may be located in one place or may be distributed over a plurality of network elements. Some or all of the components may be selected according to actual needs to achieve the object of the present disclosure.

In addition, the functional units in the various embodiments of the present disclosure may be integrated into one processing unit, or each unit may be an individual physically unit, or two or more units may be integrated into one unit.

Other embodiments of the disclosure will be apparent to those skilled in the art from consideration of the specification and practice of the embodiments disclosed herein. It is intended that the specification and examples be considered as example only and not to limit the scope of the disclosure, with a true scope and spirit of the invention is indicated by the following claims.

What is claimed is:

1. A pixel comprising:
a photoelectric converter;
a transfer transistor;
a reset transistor;
a first source follower and a second source follower, wherein:
a gate of the first source follower and a gate of the second source follower are electrically connected to a floating diffusion region between the transfer transistor and the reset transistor; and
a source of the first source follower and a source of the second source follower are connected to a row selection line via a select transistor; and
a switch device connected to the second source follower and configured to:
be turned on to allow the second source follower to work simultaneously with the first source follower; or
be turned off to allow the first source follower to work while the second source follower does not work.

2. The pixel of claim 1, wherein:
one end of the switch device is connected to the transfer transistor, and another end of the switch device is connected to the reset transistor;
the floating diffusion region includes:
a first floating diffusion region located between the transfer transistor and the switch device; and
a second floating diffusion region located between the switch device and the reset transistor; and
the gate of the first source follower is connected to the first floating diffusion region, and the gate of the second source follower is connected to the second floating diffusion region.

3. The pixel of claim 1, wherein the switch device includes a switch transistor.

4. The pixel of claim 1, wherein the photoelectric converter includes a photodiode, a phototriode, or a photomultiplier.

5. An image sensor comprising:
a pixel array including:
a pixel including:
a photoelectric converter;
a transfer transistor;
a reset transistor;
a first source follower and a second source follower, wherein:
a gate of the first source follower and a gate of the second source follower are electrically connected to a floating diffusion region between the transfer transistor and the reset transistor; and
a source of the first source follower and a source of the second source follower are connected to a row selection line via a select transistor; and
a switch device connected to the second source follower and configured to:
be turned on to allow the second source follower to work simultaneously with the first source follower; or
be turned off to allow the first source follower to work while the second source follower does not work; and
a control circuit connected to the switch device and configured to control whether the second source follower and the first source follower work simultaneously.

6. The image sensor of claim 5, wherein the control circuit is further configured to control the switch device to be turned on in response to a bright scene, or to be turned off in response to a dark scene.

7. The image sensor of claim 5, wherein:
one end of the switch device is connected to the transfer transistor, and another end of the switch device is connected to the reset transistor;
the floating diffusion region includes:
a first floating diffusion region located between the transfer transistor and the switch device; and
a second floating diffusion region located between the switch device and the reset transistor; and
the gate of the first source follower is connected to the first floating diffusion, and the gate of the second source follower is connected to the second floating diffusion region.

8. The image sensor of claim 5, wherein the switch device includes a switch transistor.

9. The image sensor of claim 5, wherein the photoelectric converter includes a photodiode, a phototriode, or a photomultiplier.

10. A pixel comprising:
a photoelectric converter;
a first transfer transistor;
a reset transistor;
a source follower, wherein:
a gate of the source follower being electrically connected to a floating diffusion region between the first transfer transistor and the reset transistor, and a source of the source follower is connected to a row selection line via a select transistor;
a second transfer transistor, wherein:
one of a source and a drain of the second transfer transistor is connected to an output terminal of the photoelectric converter; and
another one of the source and the drain of the second transfer transistor is connected to the floating diffusion region; and
a switch device connected to the second transfer transistor and configured to:
be turned on to allow the second transfer transistor to work simultaneously with the first transfer transistor; or
be turned off to allow the first transfer transistor to work while the second transfer transistor does not work.

11. The pixel of claim 10, wherein:
one end of the switch device is connected to the first transfer transistor, and another end of the switch device is connected to the reset transistor;
the floating diffusion region includes:
a first floating diffusion region located between the first transfer transistor and the switch device; and
a second floating diffusion region located between the switch device and the reset transistor; and
the another one of the source and the drain of the second transfer transistor is connected to the second floating diffusion region.

12. The pixel of claim 10, wherein a size of the second transfer transistor is larger than a size of the first transfer transistor.

13. The pixel of claim 10, wherein the switch device includes a switch transistor.

14. The pixel of claim 10, wherein the photoelectric converter includes a photodiode, a phototriode, or a photomultiplier.

15. An image sensor comprising:
a pixel array including:
a pixel including:
a photoelectric converter;
a first transfer transistor;
a reset transistor;
a source follower, wherein:
a gate of the source follower being electrically connected to a floating diffusion region between the first transfer transistor and the reset transistor, and a source of the source follower is connected to a row selection line via a select transistor;
a second transfer transistor, wherein:
one of a source and a drain of the second transfer transistor is connected to an output terminal of the photoelectric converter; and
another one of the source and the drain of the second transfer transistor is connected to the floating diffusion region; and
a switch device connected to the second transfer transistor and configured to:
be turned on to allow the second transfer transistor to work simultaneously with the first transfer transistor; or
be turned off to allow the first transfer transistor to work while the second transfer transistor does not work; and
a control circuit connected to the switch device and configured to control whether the second transfer transistor and the first transfer transistor work simultaneously.

16. The second image sensor of claim 15, wherein the control circuit is further configured to control the switch device to be turned on in a bright scene, and to be turned off in a dark scene.

17. The image sensor of claim 15, wherein:
one end of the switch device is connected to the first transfer transistor, and the other end of the switch device is connected to the reset transistor;
the floating diffusion region includes:
a first floating diffusion region located between the first transfer transistor and the switch device; and
a second floating diffusion region located between the switch device and the reset transistor; and
the another one of the source and the drain of the second transfer transistor is connected to the second floating diffusion region.

18. The image sensor of claim 15, wherein the switch device includes a switch transistor.

19. The second image sensor of claim 15, wherein the photoelectric converter includes a photodiode, a phototriode, or a photomultiplier.
